(19) United States
(12) Patent Application Publication
(10) Pub. No.: US 2024/0420966 A1
(43) Pub. Date: Dec. 19, 2024

(54) COPPER REFLOW BY SURFACE MODIFICATION

(71) Applicant: Applied Materials, Inc., Santa Clara, CA (US)

(72) Inventors: Zhiyuan Wu, San Jose, CA (US); Zheng Ju, Sunnyvale, CA (US); Feng Chen, San Jose, CA (US); Kevin Kashefi, San Ramon, CA (US); Feng Q. Liu, San Jose, CA (US); Jeffrey W. Anthis, San Jose, CA (US)

(73) Assignee: Applied Materials, Inc., Santa Clara, CA (US)

(21) Appl. No.: 18/211,044

(22) Filed: Jun. 16, 2023

(51) Int. Cl. H01L 21/3213; H01L 21/3205

(52) U.S. Cl. CPC H01L 21/32133; H01L 21/32051

(57) ABSTRACT

Embodiments of the disclosure relate to methods of etching a copper material. In some embodiments, the copper material is exposed to a halide reactant to form a copper halide species. The substrate is then heated to remove the copper halide species. In some embodiments, the etching methods are performed at relatively low temperatures. Additional embodiments of the disclosure relate to methods of copper gapfill. In some embodiments, a copper material within a substrate feature is exposed to a halide reactant to form a copper halide species. The copper halide species is then heated and flowed to fill at least a portion of the substrate feature. The reflow methods are performed at lower temperatures than similar reflow methods without formation of the copper halide species.

### TECHNICAL FIELD

Embodiments of the disclosure generally relate to methods of surface treatment to improve copper reflow. In particular, some embodiments of the disclosure provide methods of utilizing halide reactants to facilitate copper gapfill.

### BACKGROUND

Gapfill process are integral to several semiconductor manufacturing processes. A gapfill process can be used to fill a gap (or feature) with an insulating or conducting material. For example, shallow trench isolation, inter-metal dielectric layers, passivation layers, dummy gate, are all typically implemented by gapfill processes.

As device geometries continue to shrink (e.g., critical dimensions <20 nm, <10 nm, and beyond) and thermal budgets are reduced, defect-free filling of spaces becomes increasingly difficult due to the limitations of conventional deposition processes.

Most conventional deposition methods, especially chemical vapor deposition (CVD) methods, deposit more material on the substrate surface than within the feature, particularly near the bottom of a feature. As a result, the film on the substrate surface must be removed through an etch process before the opening of the feature closes and creates a void within the feature.

Other gapfill methods rely on atomic layer deposition to form metal gapfill materials. These methods typically produce conformal films on all the substrate surfaces. Accordingly, these methods also require an etch of material deposited outside the feature, but they also often produce gapfill with a seam in the middle as films form from the sidewalls and meet in the middle.

Accordingly, there is a need for methods of removing metal gapfill materials, specifically copper, from the substrate surface outside of a feature without affecting the material deposited within the feature.

Copper provides unique material characteristics. It is highly conductive, and can also be processed so as to have copper material from the substrate field “reflow” into the substrate feature. In so doing, the feature is filled with a seam-free, void-free gapfill material, even at small critical dimensions (e.g., less than or equal to 12 nm). Unfortunately, commonly used reflow processes use relatively high temperatures which can lead to film agglomeration, particularly with the thinner films used at lower critical dimensions.

Accordingly, there is a need for improved methods of copper reflow which are performed at relatively low processing temperatures.

### SUMMARY

One or more embodiments of the disclosure are directed to a copper etching method comprising: exposing a copper surface to a halide reactant to form a copper halide species; and heating the substrate to a temperature in a range of about 150° C. to about 350° C. to remove the copper halide species.

Additional embodiments of the disclosure are directed to a copper gapfill method comprising: exposing a copper material within a substrate feature to a halide reactant to form a copper halide species; and reflowing the copper halide species to fill at least a portion of the substrate feature. Reflowing the copper material and the copper halide species is performed at a lower temperature than a copper gapfill method without formation of the copper halide species.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 illustrates an exemplary substrate during processing according to one or more embodiments of the disclosure;

FIG. 2 illustrates an exemplary substrate during processing according to one or more embodiments of the disclosure; and

FIG. 3 illustrates an exemplary cluster tool according to one or more embodiments of the disclosure.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

As used in this specification and the appended claims, the terms “precursor,” “reactant,” “reactive gas” and the like are used interchangeably to refer to any gaseous species that can react with the substrate surface.

The term “about” as used herein means approximately or nearly and in the context of a numerical value or range set forth means a variation of ±15% or less, of the numerical value. For example, a value differing by ±14%, ±10%, ±5%, ±2%, ±1%, ±0.5%, or ±0.1% would satisfy the definition of “about.”

As used in this specification and the appended claims, the term “substrate” refers to a surface, or portion of a surface, upon which a process acts. It will also be understood by those skilled in the art that reference to a substrate can also refer to only a portion of the substrate, unless the context clearly indicates otherwise. Additionally, reference to depositing on a substrate can mean both a bare substrate and a substrate with one or more films or features deposited or formed thereon

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal, UV cure, e-beam cure and/or bake the substrate surface. In addition to film processing directly on the surface of the substrate itself, in the present disclosure, any of the film processing steps disclosed may also be performed on an underlayer formed on the substrate as disclosed in more detail below, and the term “substrate surface” is intended to include such underlayer as the context indicates.

As used in this disclosure and the appended claims, the term “on”, with respect to a film or a layer of a film, includes the film or layer being directly on a surface, for example, a substrate surface, as well as there being one or more underlayers between the film or layer and the surface, for example the substrate surface. Thus, in some embodiments, the phrase “on the substrate surface” is intended to include one or more underlayers. In other embodiments, the phrase “directly on” refers to a layer or a film that is in contact with a surface, for example, a substrate surface, with no intervening layers. Thus, the phrase “a layer directly on the substrate surface” refers to a layer in direct contact with the substrate surface with no layers in between.

One or more embodiments of the disclosure are directed to methods for improving copper reflow. Some embodiments of the disclosure facilitate copper reflow by removing a portion of a copper material from near a feature opening. In some embodiments, the copper removal prevents the feature from prematurely closing during reflow. In some embodiments, the methods advantageously provide removal of the portion of the copper material at relatively low temperatures. Some embodiments of the disclosure advantageously provide methods of copper reflow performed at relatively low temperatures.

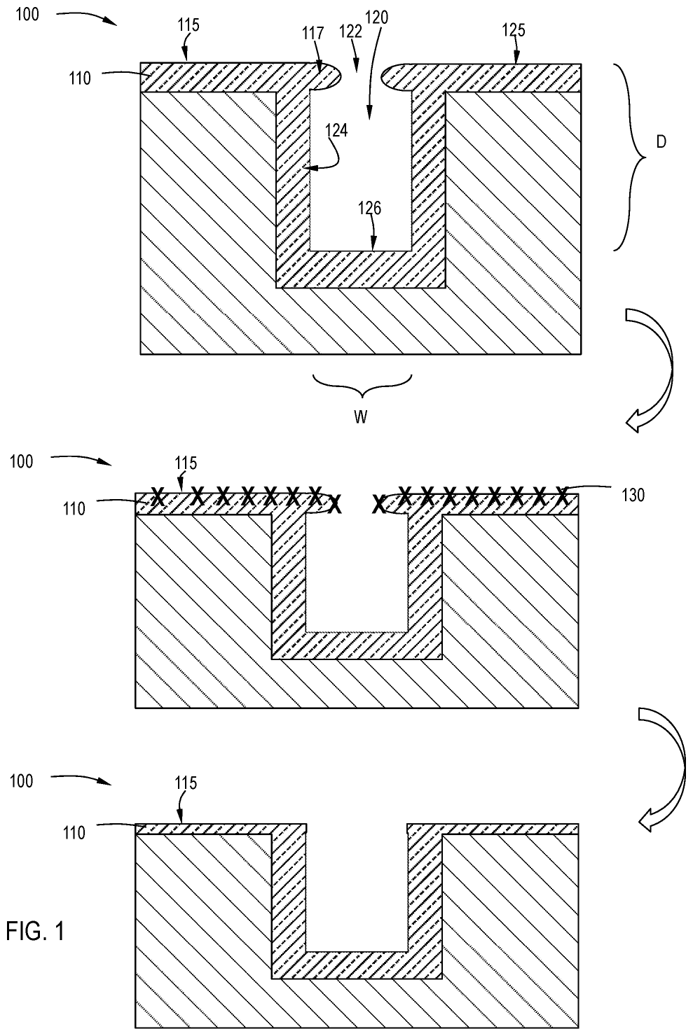

Referring to FIG. 1, a copper etching or removal process is disclosed. The method begins with a substrate 100 with a copper material 110 thereon. The copper material 110 has a copper surface 115.

In some embodiments, the substrate 100 has a feature 120 formed therein. While only a single feature is shown in the Figures, one skilled in the art will recognize that a plurality of features will be affected by the disclosed methods, each in a similar manner.

The feature 120 has an opening 122 with a width W. The opening 122 is formed at a top surface 125. The feature 120 also has one or more sidewall 124 and extends a depth D from the top surface 125 to a bottom 126. While straight, vertical sidewalls are shown in the Figures, the disclosed methods may also be performed on slanted, irregular or reentrant sidewalls.

While the disclosure herein is made with respect to a copper material covering a feature 120, those skilled in the art will recognize that the methods disclosed herein may be equally relevant to copper materials on other substrate shapes or blanket copper materials on a substrate.

In some embodiments, the copper material 110 may create an overhang portion 117 on the top surface 125 near the opening 122. The overhang portion 117 may partially obstruct or block the opening 122 of the feature 120. The overhang portion 117 may reduce the width of the opening. In some embodiments, the reduced width makes further deposition within the feature difficult.

The copper surface 115 is exposed to a halide reactant to form a copper halide species 130 on the copper surface 115. After formation of the copper halide species 130, the substrate 100 is heated to remove the copper halide species.

Without being bound by theory, it is believed that the copper halide species 130 is more readily etched at a lower temperature than the copper surface 115. In some embodiments, the copper halide species 130 is formed on the copper material 110 outside of the feature 120 but not formed on the copper material 110 within the feature 120. Accordingly, in some embodiments, the method preferentially etches the copper material 110 outside of the feature 120 without etching the copper material within the feature 120. In some embodiments, the method preferentially etches the copper material 110 of the overhang portion 117.

In some embodiments, the halide reactant comprises any suitable halide atoms. In some embodiments, the halide reactant does not contain fluorine. In some embodiments, the halide reactant does not contain chlorine. In some embodiments, the halide reactant comprises or consists essentially of bromine and/or iodine. As used in this regard, a reactant which “consists essentially of” a stated halide contains greater than or equal to about 95%, greater than or equal to about 98%, greater than or equal to about 99%, or greater than or equal to about 99.5% of the stated halide on an atomic count basis relative to any all halide atoms.

In some embodiments, the halide reactant comprises an alkyl halide. As used in this regard, an alkyl halide is a hydrocarbon where one or more atoms of hydrogen has been replaced by a halogen. In some embodiments, the alkyl halide comprises less than or equal to 10 carbon atoms, less than or equal to 6 carbon atoms, less than or equal to 4 carbon atoms, or less than or equal to 2 carbon atoms. In some embodiments, the alkyl halide comprises one halogen atom. In some embodiments, the alkyl halide comprises two halide atoms. In some embodiments, the alkyl halide comprises or consists essentially of a species with the general formula CₙH₂ₙ₊₂₋ₐXₐ, where n is 1-10, a is 1 or 2, and X is I, Br, or Cl.

In some embodiments, the halide reactant comprises or consists essentially of iodoethane (H₅C₂I) or diiodomethane (CH₂I₂). In some embodiments, the halidie reactant comprises or consists essentially of dibromomethane (CH₂Br₂), tribromomethane (CHBr₃), or bromoethane (C₂H₅Br). As used in this regard, a halide reactant which “consists essentially of” a stated compound contains greater than or equal to about 95%, greater than or equal to about 98%, greater than or equal to about 99%, or greater than or equal to about 99.5% of the stated compound on a molar basis relative to all other halide-containing compounds.

In some embodiments, the copper halide species comprises CuX or CuX₂, where X identifies a halide.

In some embodiments, the substrate 100 is heated to a temperature in a range of about 150° C. to about 350° C. In some embodiments, the temperature is in a range of about 200° C. to about 350° C., in a range of about 150° C. to about 300° C., or in a range of about 200° C. to about 300° C.

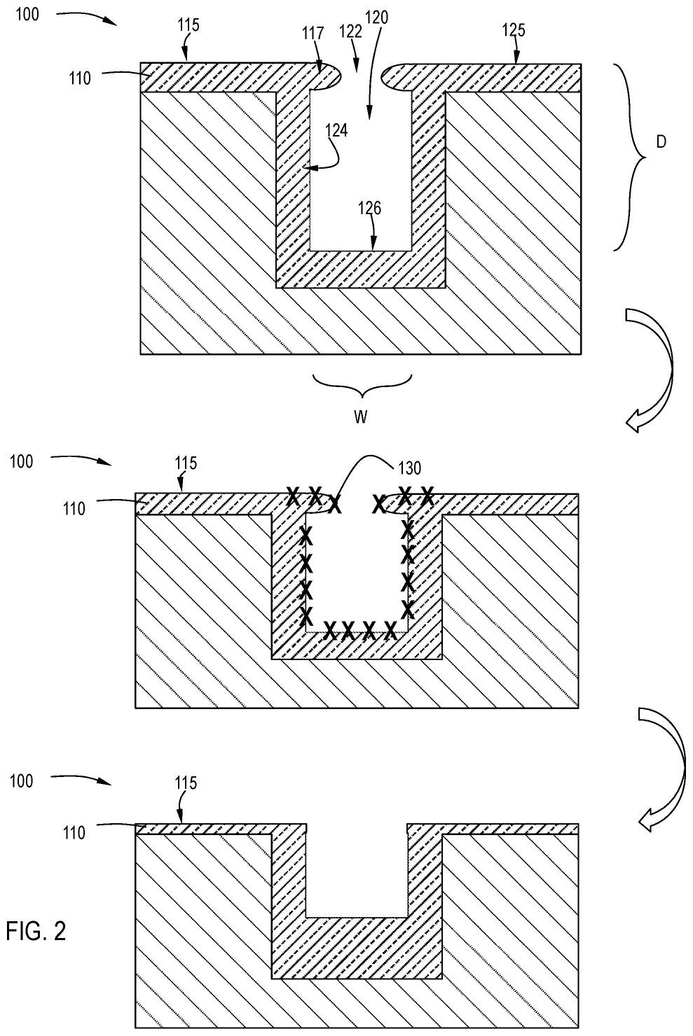

Referring to FIG. 2, a copper gapfill method is disclosed. The method begins with a substrate similar to that disclosed with respect to FIG. 1, including a copper material 110 on a substrate 100, the copper material within a feature 120. In some embodiments, the copper material 110 forms an overhang portion 117 near the opening 122 of the feature 120.

The method exposes the copper material 110 to a halide reactant to form a copper halide species. In some embodiments, the copper halide species 130 is formed within the feature 120.

The copper halide species 130 are reflowed to fill at least a portion of the feature 120. In some embodiments, the copper material 110 is also reflowed. The reflow process is performed at a lower temperature than a copper gapfill or copper reflow process without the formation of the copper halide species 130.

Without being bound by theory, it is believed that the copper halide species 130 has a lower melting point than the copper material 110. Accordingly, the copper halide species 130 provides better reflow (e.g., greater surface diffusion and/or less bulk agglomeration) at relatively lower temperatures than reflow of the coper material without formation of the copper halide species. In some embodiments, the copper halide species 130 is heater to no more than 300° C., no more than 250° C., or no more than 200° C. during reflow.

The halide reactant of the reflow process described above may be the same as the halide reactant described above with respect to the copper etching method.

In some embodiments, the substrate is maintained at a temperature in a range of about 50° C. to about 300° C. In some embodiments, the disclosed methods may be performed at a processing pressure in a range of about 1 Torr to about 100 Torr. In some embodiments, the halide reactant may be flowed at a rate of about 1 sccm to about 500 sccm. In some embodiments, the halide reactant is diluted with argon.

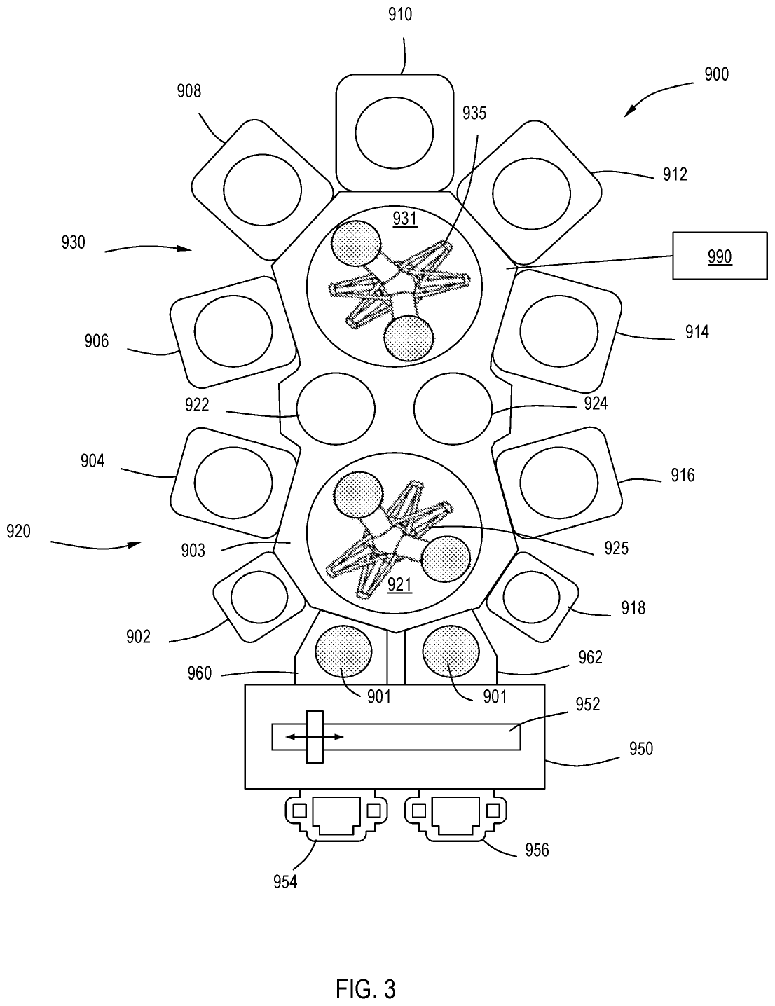

Additional embodiments of the disclosure are directed to a cluster tool 900 for the formation of the devices and methods described, as shown in FIG. 3. A variety of multi-processing platforms, including the Centura®, Dual ACP, Producer® GT, and Endura® platform, available from Applied Materials® as well as other processing systems may be utilized. In one or more embodiments, the cluster tool 900 includes a transfer station 921, 931 with a plurality of sides. A robot 925, 935 is positioned within the transfer station 921, 931 and is configured to move a robot blade and a wafer to each of the plurality of sides.

The cluster tool 900 comprises a plurality of processing chambers 902, 904, 906, 908, 910, 912, 914, 916, and 918, also referred to as process stations, connected to the central transfer station. The various processing chambers provide separate processing regions isolated from adjacent process stations. The processing chamber can be any suitable chamber including, but not limited to, a metal deposition chamber; a metal halide exposure chamber; a metal etching chamber; a metal reflow chamber; a pre-clean chamber; transfer space(s), a wafer orienter/degas chamber, a cryo cooling chamber, and the like. The particular arrangement of process chambers and components can be varied depending on the cluster tool and should not be taken as limiting the scope of the disclosure.

In one or more embodiments, the cluster tool 900 includes a copper deposition chamber. In one or more embodiments, the cluster tool 900 includes a pre-cleaning chamber connected to the central transfer station.

In the embodiment shown in FIG. 4, a factory interface 950 is connected to a front of the cluster tool 900. The factory interface 950 includes a loading chamber 954 and an unloading chamber 956 on a front 951 of the factory interface 950. While the loading chamber 954 is shown on the left and the unloading chamber 956 is shown on the right, those skilled in the art will understand that this is merely representative of one possible configuration.

The size and shape of the loading chamber 954 and unloading chamber 956 can vary depending on, for example, the substrates being processed in the cluster tool 900. In the embodiment shown, the loading chamber 954 and unloading chamber 956 are sized to hold a wafer cassette with a plurality of wafers positioned within the cassette.

A robot 952 is within the factory interface 950 and can move between the loading chamber 954 and the unloading chamber 956. The robot 952 is capable of transferring a wafer from a cassette in the loading chamber 954 through the factory interface 950 to load lock chamber 960. The robot 952 is also capable of transferring a wafer from the load lock chamber 962 through the factory interface 950 to a cassette in the unloading chamber 956. As will be understood by those skilled in the art, the factory interface 950 can have more than one robot. For example, the factory interface 950 may have a first robot that transfers wafers between the loading chamber 954 and load lock chamber 960, and a second robot that transfers wafers between the load lock chamber 962 and the unloading chamber 956.

The cluster tool 900 shown has a first section 920 and a second section 930. The first section 920 is connected to the factory interface 950 through load lock chamber 960, 962. The first section 920 includes a transfer station 921 with a robot 925 positioned therein. The robot 925 is also referred to as a robotic wafer transport mechanism. The transfer station 921 is centrally located with respect to the load lock chamber 960, 962, processing chamber 902, 904, 916, 918, and pass-through chamber 922, 924. The robot 925 of some embodiments is a multi-arm robot capable of independently moving more than one wafer at a time. In one or more embodiments, the transfer station 921 comprises more than one robotic wafer transfer mechanism. The robot 925 in transfer station 921 is configured to move wafers between the chambers around the transfer station 921. Individual wafers are carried upon a wafer transport blade that is located at a distal end of the first robotic mechanism.

After processing a wafer in the first section 920, the wafer can be passed to the second section 930 through a pass-through chamber. For example, chambers 922, 924 can be uni-directional or bi-directional pass-through chambers. The pass-through chambers 922, 924 can be used, for example, to cryo cool the wafer before processing in the second section 930 or allow wafer cooling or post-processing before moving back to the first section 920.

A system controller 990 is in communication with robot 925, robot 935, first plurality of processing chambers 902, 904, 916, 918 and second plurality of processing chambers 906, 908, 910, 912, 914. The system controller 990 can be any suitable component that can control the processing chambers and robots. For example, the system controller 990 can be a computer including a central processing unit, memory, suitable circuits, and storage.

Processes may generally be stored in the memory of the system controller 990 as a software routine that, when executed by the processor, causes the process chamber to perform processes of the present disclosure. The software routine may also be stored and/or executed by a second processor (not shown) that is remotely located from the hardware being controlled by the processor. Some or all of the method of the present disclosure may also be performed in hardware. As such, the process may be implemented in software and executed using a computer system, in hardware as, e.g., an application specific integrated circuit or other type of hardware implementation, or as a combination of software and hardware. The software routine, when executed by the processor, transforms the general-purpose computer into a specific purpose computer (controller) that controls the chamber operation such that the processes are performed.

In one or more embodiments, the cluster tool 900 comprises a transfer station 921, 931 comprising a robot 925, 935 configured to move a wafer; one or more of a deposition station, a halide reactant exposure station, and/or an etching or reflow station, connected to the central transfer station; an optional pre-clean station connected to the central transfer station; and at least one controller connected to the one or more of the central transfer station, deposition station, a halide reactant exposure station, am etching or reflow station, or the optional pre-clean station. In one or more embodiments, the at least one controller has at least one configuration selected from: a configuration to move the wafer between stations using the robot; a configuration to deposit copper material on a substrate feature; a configuration to expose the copper material to a halide reactant; a configuration to etch the copper halide species; a configuration to reflow the halide species; and/or a configuration to pre-clean the wafer.

In one or more embodiments, a processing tool comprises: a pre-clean chamber having a substrate support therein; a deposition chamber; a halide reactant exposure chamber; an etching chamber; a reflow chamber; a robot configured to access the pre-clean chamber, the deposition chamber, the halide reactant exposure chamber, the etching chamber, and/or the reflow chamber; and a controller connected to each of the chambers and the robot, the controller having one or more configurations selected from: cleaning a substrate, depositing a copper material on the substrate, exposing the copper material to a halide reactant, and etching or reflowing the copper halide species.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, those skilled in the art will understand that the embodiments described are merely illustrative of the principles and applications of the present disclosure. It will be apparent to those skilled in the art that various modifications and variations can be made to the method and apparatus of the present disclosure without departing from the spirit and scope of the disclosure. Thus, the present disclosure can include modifications and variations that are within the scope of the appended claims and their equivalents.

What is claimed is:

1. A copper etching method comprising:
exposing a copper surface to a halide reactant to form a copper halide species; and
heating the substrate to a temperature in a range of about 150° C. to about 350° C. to remove the copper halide species.

2. The method of claim 1, wherein the copper halide species is formed on a copper material outside of a substrate feature but not formed on the copper material within the substrate feature.

3. The method of claim 1, wherein the halide reactant does not contain fluorine.

4. The method of claim 1, wherein the halide reactant does not contain chlorine.

5. The method of claim 1, wherein the halide reactant comprises bromine or iodine.

6. The method of claim 1, wherein the halide reactant comprises an alkyl halide.

7. The method of claim 1, wherein the halide reactant consists essentially of consists essentially of iodoethane (H₅C₂I) or diiodomethane (CH₂I₂).

8. The method of claim 1, wherein the copper halide species comprises CuX.

9. The method of claim 1, wherein the copper halide species comprises CuX₂.

10. A copper etching method comprising:
exposing a copper surface to a bromide reactant to form a copper bromide species comprising CuBr₂; and
heating the substrate to a temperature in a range of about 150° C. to about 300° C. to remove the copper bromide species.

11. The method of claim 10, wherein the bromide reactant consists essentially of dibromomethane (CH₂Br₂), tribromomethane (CHBr₃), or bromoethane (C₂H₅Br).

12. A copper gapfill method comprising:
exposing a copper material within a substrate feature to a halide reactant to form a copper halide species; and
reflowing the copper halide species to fill at least a portion of the substrate feature,
wherein reflowing the copper material and the copper halide species is performed at a lower temperature than a copper gapfill method without formation of the copper halide species.

13. The method of claim 12, wherein the copper halide species are heated to no more than 300° C. during reflow.

14. The method of claim 12, wherein the halide reactant does not contain fluorine.

15. The method of claim 12, wherein the halide reactant does not contain chlorine.

16. The method of claim 12, wherein the halide reactant comprises bromine or iodine.

17. The method of claim 12, wherein the halide reactant comprises an alkyl halide.

18. The method of claim 12, wherein the halide reactant consists essentially of consists essentially of iodoethane (H₅C₂I) or diiodomethane (CH₂I).

19. The method of claim 12, wherein the copper halide species comprises CuX.

20. The method of claim 12, wherein the copper halide species comprises CuX₂.
